(19) United States
(12) Patent Application Publication
(10) Pub. No.: US 2008/0093646 A1
(43) Pub. Date: Apr. 24, 2008

(54) Non-volatile memory device and method for fabricating the same

(75) Inventors: Yong-Kyu Lee, Gwacheon (KR); Jeong-Uk Han, Suwon-si (KR); Hee-Seog Jeon, Suwon-si (KR); Young Ho Kim, Hwaseong-si (KR); Myung-Jo Chun, Hwaseong-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/602,075

(22) Filed: Nov. 20, 2006

(30) Foreign Application Priority Data
Oct. 18, 2006 (KR) 10-2006-0101256

(51) Int. Cl. H01L 29/76

(52) U.S. Cl. 257/314

(57) ABSTRACT

A non-volatile memory device comprises a semiconductor substrate having source/drain regions formed at both ends of a channel region, a gate structure forming an offset region by being separated a predetermined distance from the source region and comprising a charge accumulation region and a control gate sequentially deposited in the channel region to at least partially overlap the drain region, and a spacer arranged at each of both side walls of the gate structure. A threshold voltage value of the offset region changes depending on a dielectric constant of the spacer.

### CROSS-REFERENCE TO RELATED PATENT APPLICATIONS

This application claims the benefit of Korean Patent Application No. 10-2006-0101256, filed on 18 Oct., 2006, in the Korean Intellectual Property Office, the contents of which are incorporated herein in their entirety by reference.

### BACKGROUND OF THE INVENTION

1. Field of the Invention

The present invention relates to a semiconductor device and a method for fabricating the same, and more particularly, to a non-volatile memory device and a method for fabricating the same.

2. Description of the Related Art

Non-volatile memory devices are those whose data is not erased when the power supply is discontinued, unlike DRAM (dynamic random access memory) and SRAM (static random access memory) devices. Types of non-volatile memory devices include a flash memory device which is classified into a NAND flash device used for a large capacity memory device and a NOR flash device capable of a high speed random access according to array architectures and purposes.

In the NOR flash device, during scale-down to sizes under 100 nm, a drop of a voltage Vds between source/drain regions is characteristically generated due to a punch-through phenomenon. In particular, in a flash memory device comprising a floating gate, as the device is scaled down, a drain-floating gate couple ratio increases so that a drain turn-on is generated, causing programming errors.

### SUMMARY OF THE INVENTION

To solve the above and/or other problems, the present invention provides a non-volatile memory device which can prevent the generation of a program defect and select a programming method according to the application field of the device.

The present invention provides a method for fabricating a non-volatile memory device which can prevent the generation of a program defect and select a programming method according to the application field of the device.

According to an aspect of the present invention, a non-volatile memory device comprises a semiconductor substrate having source/drain regions formed at both ends of a channel region, a gate structure forming an offset region by being separated a predetermined distance from the source region and comprising a charge accumulation region and a control gate sequentially deposited in the channel region to at least partially overlap the drain region, and a spacer arranged at each of both side walls of the gate structure. A threshold voltage value of the offset region changes depending on a dielectric constant of the spacer.

The spacer may comprise a high-dielectric-constant material and the high-dielectric-constant material can be at least one material selected from silicon nitride (Si₃N₄), aluminum oxide (Al₂O₃), and hafnium oxide (HfO₂). When the spacer comprises the high-dielectric-constant material, the device may be programmed using a channel hot electron (CHE) injection method.

The spacer may comprise a low-dielectric-constant material which is at least one material selected from fluorinated silica glass and porous silicon oxide (SiO₂). When the spacer comprises the low-dielectric-constant material, the device may be programmed using an FN tunneling method.

The drain region may comprise a low concentration doping region substantially aligned along the side wall of the gate structure and a high concentration doping region substantially aligned along an end portion of the spacer.

The charge accumulation region may comprise a deposition structure of a tunnel insulation film, a floating gate, and a blocking insulation film.

The charge accumulation region may comprise a deposition structure of a tunnel insulation film, a nitride-based charge trap film, and a blocking insulation film.

According to another aspect of the present invention, a method for fabricating a non-volatile memory device comprises forming a gate structure comprising a charge accumulation region and a control gate on a semiconductor substrate, forming a spacer arranged at both side walls of the gate structure and comprising a high- or low-dielectric-constant material, forming a drain region in the semiconductor substrate using the gate structure and the spacer as ion implantation masks, and forming a source region in the semiconductor substrate using the gate structure and the spacer as ion implantation masks.

The drain region and the source region may be simultaneously or separately formed.

The method may further comprise forming a low concentration doping region of the drain region using the gate structure as an ion implantation mask before the spacer is formed.

The high-dielectric-constant material may be at least one material selected from silicon nitride (Si₃N₄), aluminum oxide (Al₂O₃), and hafnium oxide (HfO₂).

The low-dielectric-constant material may be at least one material selected from fluorinated silica glass and porous silicon oxide (SiO₂).

The charge accumulation region may comprise a deposition structure of a tunnel insulation film, a floating gate, and a blocking insulation film.

The charge accumulation region may comprise a deposition structure of a tunnel insulation film, a nitride-based charge trap film, and a blocking insulation film.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is a cross-sectional view of a non-volatile memory device according to an embodiment of the present invention.

FIG. 2 is an equivalent circuit diagram of the non-volatile memory device of FIG. 1.

FIG. 3 is a cross-sectional view illustrating the non-volatile memory device of FIG. 1 programmed in a channel hot electron injection method;

FIG. 4 is a cross-sectional view illustrating the non-volatile memory device of FIG. 1 programmed in an FN tunneling method.

FIG. 5 is a cross-sectional view of a non-volatile memory device according to another embodiment of the present invention.

FIG. 6 is a circuit diagram illustrating the structure of a cell embodied by the non-volatile memory device of FIG. 1.

FIG. 7 is a cross-sectional view illustrating a programming method of the non-volatile memory device of FIG. 1.

FIGS. 8A and 8B are cross-sectional views illustrating an erasing method of the non-volatile memory device of FIG. 1.

FIGS. 9A and 9B are cross-sectional views illustrating another programming method of the non-volatile memory device of FIG. 1.

FIGS. 10A and 10B are cross-sectional views illustrating another erasing method of the non-volatile memory device of FIG. 1.

FIGS. 11A and 11B are cross-sectional views illustrating a determination method of the non-volatile memory devices according to embodiments of the invention.

FIG. 12 is a flow chart illustrating a method for fabricating a non-volatile memory device according to an embodiment of the present invention.

FIGS. 13 through 17 are cross-sectional views sequentially arranging the steps of the fabricating method of FIG. 12.

FIG. 18 is a flow chart illustrating a method for fabricating a non-volatile memory device according to another embodiment of the present invention.

FIG. 19 is a cross-sectional view illustrating an intermediate structure during the fabricating method of FIG. 18.

### DETAILED DESCRIPTION OF PREFERRED EMBODIMENTS OF THE INVENTION

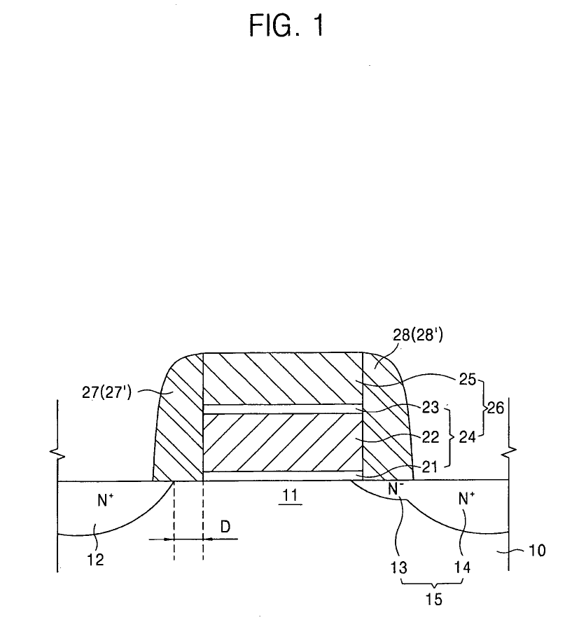

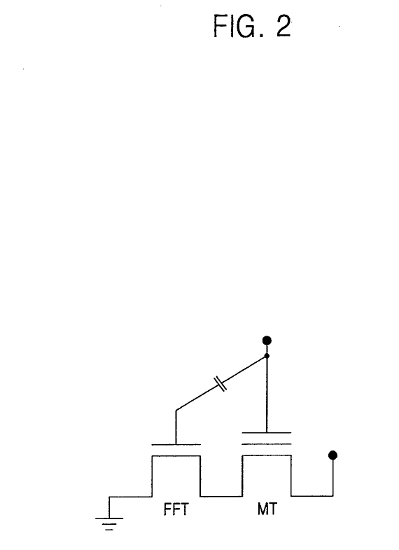

A non-volatile memory device according to an embodiment of the present invention will be described with reference to FIGS. 1 and 2. FIG. 1 is a cross-sectional view of a non-volatile memory device according to an embodiment of the present invention. FIG. 2 is an equivalent circuit diagram of the non-volatile memory device of FIG. 1. In the following description, although a memory transistor of the non-volatile memory device is an n-MOSFET (metal-oxide semiconductor field effect transistor), each of the embodiments described below includes other complementary embodiments.

As shown in FIG. 1, a memory transistor of a non-volatile memory device according to an embodiment of the present invention comprises a gate structure 26 provided on a P-type semiconductor substrate 10 and spacers 27, 27′, 28, and 28′ arranged on both side walls of the gate structure 26. The P-type semiconductor substrate 10 comprises source/drain regions 12 and 15 formed at both sides of a channel region 11. The gate structure 26 comprises a charge accumulation region 24 and a control gate 25.

The source region 12 located at one side of the channel region 11 in the semiconductor substrate 10 is doped with, for example, high concentration N-type impurity ions N⁺. Also, the drain region 15 comprises a region (hereinafter referred to as the low concentration doping region 13) close to the channel region 11 and doped with low concentration N-type impurity ions N⁻ and a region (hereinafter referred to as the high concentration doping region 14) close to the low concentration doping region 13 and doped with high concentration N-type impurity ions N⁺. In the drain region 15, the low concentration doping region 13 that is close to the channel region 11 may have a lightly doped drain (LDD) structure or, although it is now shown in the drawing, a mask island double diffused drain (DDD) structure by defining the high concentration doping region 14 in the low concentration doping region 13.

The gate structure 26 comprising the charge accumulation region 24 and the control gate 25 is separated a predetermined distance from an end portion of the source region 12 on the semiconductor substrate 10 and at least partially overlaps the drain region 15. That is, an offset region D that does not overlap the gate structure 26 and the source region 12 exists.

Since the offset region D is of high resistance, when a voltage applied to the control gate 25 and the drain region 15 is relatively low, a strong field enhancement is generated in the channel at the side of the source region 12. Hot electrons that obtain energy by the high electric field can be injected in the charge accumulation region 24. Also, in view of consumption current during programming, even when a high voltage is applied to the control gate 25, since current that is weakly inversed by a gate voltage flows in the offset region D, power consumption can be minimized.

In the gate structure 26, the charge accumulation region 24 that accumulates electrons injected from the channel region 11 comprises, for example, a deposition structure of a tunnel insulation film 21, a floating gate 22, and a blocking insulation film 23 stacked sequentially on the semiconductor substrate 10. The tunnel insulation film 21 can be formed of, for example, silicon oxide SiO₂. Also, the floating gate 22 where the electrons injected from the channel region 11 are substantially accumulated can be formed of, for example, doped polysilicon. The blocking insulation film 23 located on the floating gate 22 can be formed of, for example, silicon oxide SiO₂ or may have an ONO (oxide-nitride-oxide) structure.

Also, the control gate 25 located on the charge accumulation region 24 can be formed of doped polysilicon. As described above, the gate structure 26 may have a double gate structure comprising the floating gate 22 and the control gate 25.

The spacers 27, 27′, 28, and 28′ are arranged at both side walls of the gate structure 26 that comprises the charge accumulation region 24 and the control gate 25. By controlling the dielectric constant of the spacers 27, 27′, 28, and 28′ a turn-on threshold voltage (turn-on Vth) between the source region 12 and the channel region 11 can be changed. The equivalent circuit diagram of FIG. 2 conceptually shows that a non-volatile memory device of FIG. 1 can be used as a transistor caused by a sort of a fringe field (hereinafter referred to as the fringe field transistor (FFT)) by controlling the dielectric constant of the spacers 27, 27′, 28, and 28′ of FIG. 1. In FIG. 2, “MT” stands for a memory transistor.

Referring back to FIG. 1, the spacers 27, 27′, 28, and 28′ may comprise a material (hereinafter referred to as the high-dielectric-constant material) having a high dielectric constant k (high k) or a material (hereinafter referred to as the low-dielectric-constant material) having a low dielectric constant k (low k). The high k means to have a relatively higher dielectric constant than that of silicon oxide (SiO₂). Also, the low k means to have a relatively lower dielectric constant than that of silicon oxide (SiO₂).

The high k material used for the spacers 27, 27′, 28, and 28′ comprises, for example, silicon nitride (Si₃N₄), aluminum oxide (Al₂O₃), or hafnium oxide (HfO₂). The low k material used for the spacers 27, 27′, 28, and 28′ comprises, for example, fluorinated silica glass obtained by doping fluorine in silicon oxide or porous silicon oxide (SiO₂) including air. It is obvious to those skilled in the art that the high k material or low k material can be replaced by other well-known materials which can achieve the main purpose of the present invention.

Although it is not shown in the drawings, the upper surface of the memory transistor is covered with an interlayer insulation film (not shown) and the drain region 15 of the memory transistor and a bit line located on the interlayer insulation film are electrically connected through a contact hole (not shown) in the interlayer insulation film.

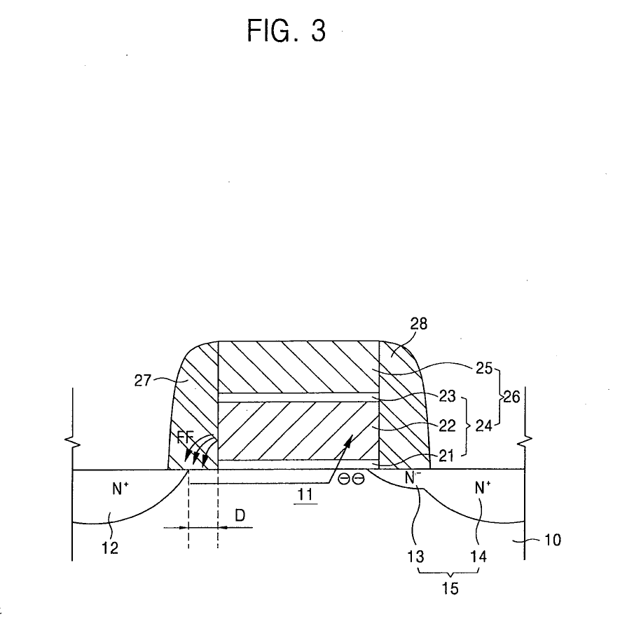

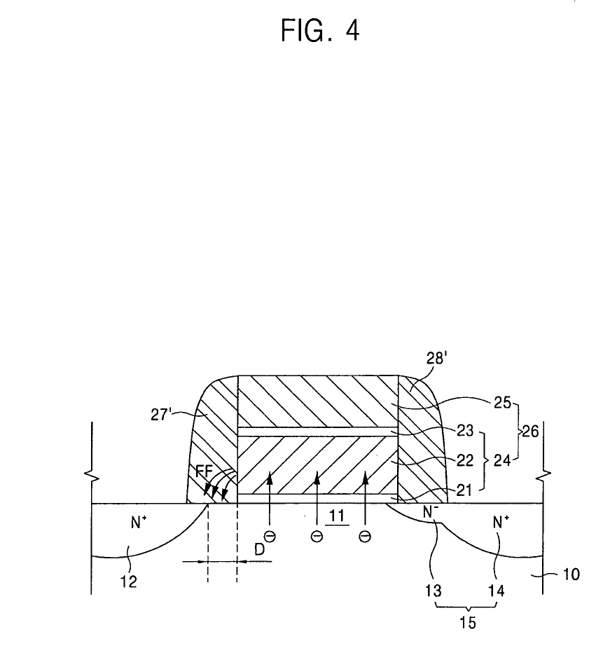

Next, the principle of programming of the non-volatile memory device according to the present invention will be described with reference to FIGS. 3 and 4. FIG. 3 is a cross-sectional view illustrating the non-volatile memory device of FIG. 1 programmed in a channel hot electron injection method. FIG. 4 is a cross-sectional view illustrating the non-volatile memory device of FIG. 1 programmed in an FN (Fowler-Nordheim) tunneling method.

As shown in FIG. 3, when the non-volatile memory device according to the present invention comprises the spacers 27 and 28 formed of a high k material, in detail, a NOR flash device having the spacers 27 and 28 having a high k, even when a relatively low voltage is applied to the control gate 25, a relatively large fringe field FF is generated by the spacer 27 having a high k so that the offset region D is reversed. Electrons are injected from the source region 12 to the channel region 11 through the offset region D reversed to the fringe field FF and accelerated so that the electrons are injected in the floating gate 22 of the charge accumulation region 24. A selected cell is programmed in the above-described channel hot electron (CHE) injection method.

As shown in FIG. 4, when the non-volatile memory device according to the present invention comprises the spacers 27′ and 28′ formed of a low k material, in detail, a NOR flash device having the spacers 27′ and 28′ having a low k, a low fringe field is generated due to the spacers 27′ and 28′ having a low k. Accordingly, even when a relatively high gate voltage is applied to the control gate 25, the offset region D of the source region 12 is not turned on. Thus, the electrons accelerated from the channel region 11 in the FN tunneling method are injected in the floating gate 22 of the charge accumulation region 24.

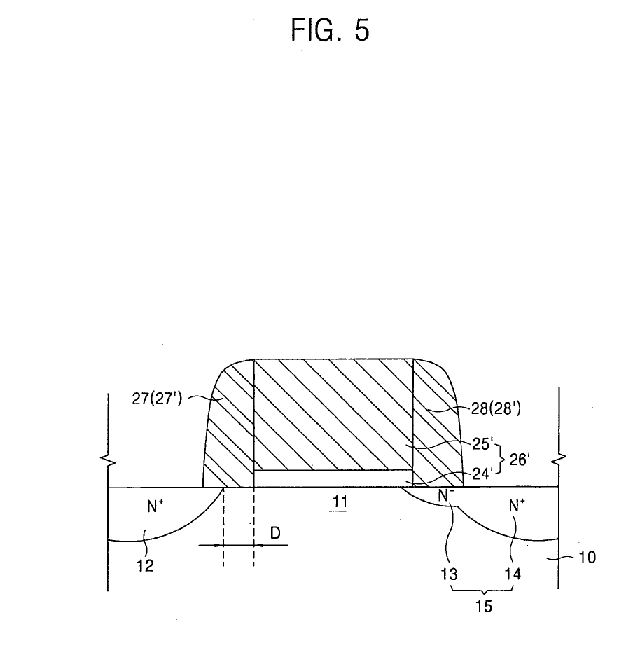

Next, a non-volatile memory device according to another embodiment of the present invention will be described with reference to FIG. 5. FIG. 5 is a cross-sectional view of a non-volatile memory device according to another embodiment of the present invention. Since the non-volatile memory device according to another embodiment of the present invention is substantially the same as the non-volatile memory device according to the above-described embodiment, the non-volatile memory device according to another embodiment of the present invention will be described mainly in connection with the charge accumulation region.

A memory transistor of the non-volatile memory device according to another embodiment of the present invention comprises a gate structure 26′ having a charge accumulation region 24′ and a control gate 25′ and formed on the semiconductor substrate 10 having the source/drain regions 12 and 15 formed at both sides of the channel region 11, and the spacers 27, 27′, 28, and 28′ arranged at both side walls of the gate structure 26′ and formed of a high k or low k material. The offset region D that does not overlap the gate structure 26′ is formed in the source region 12.

The charge accumulation region 24′ of the gate structure 26′ may have a deposition structure in which a tunnel insulation film, a nitride-based charge trap film, and a blocking insulation film are sequentially deposited from the semiconductor substrate 10. The tunnel insulation film can be formed of, for example, silicon oxide (SiO₂). The nitride-based charge trap film where electrons are substantially accumulated can be formed of silicon nitride (Si₃N₄). Also, the blocking insulation film can be formed of silicon oxide (SiO₂), aluminum oxide (Al₂O₃), or hafnium oxide (HfO₂). The control gate 25′ located on the charge accumulation region 24′ can be doped polysilicon or metal, for example, tantalum (Ta).

The memory transistor comprising the gate structure 26′ may have a SONOS structure of polysilicon/oxide/nitride/oxide/silicon or MONOS structure of metal/oxide/nitride/oxide/silicon, for example, a TANOS structure of tantalum/oxide/nitride/oxide/silicon.

The structure of a cell that can be embodied by the non-volatile memory devices according to the above embodiments will be described below. Although in the present specification the non-volatile memory devices according to the embodiments of the present invention are described as those being embodied in a NOR cell structure, the non-volatile memory devices can be embodied in a variety of cell structures as necessary.

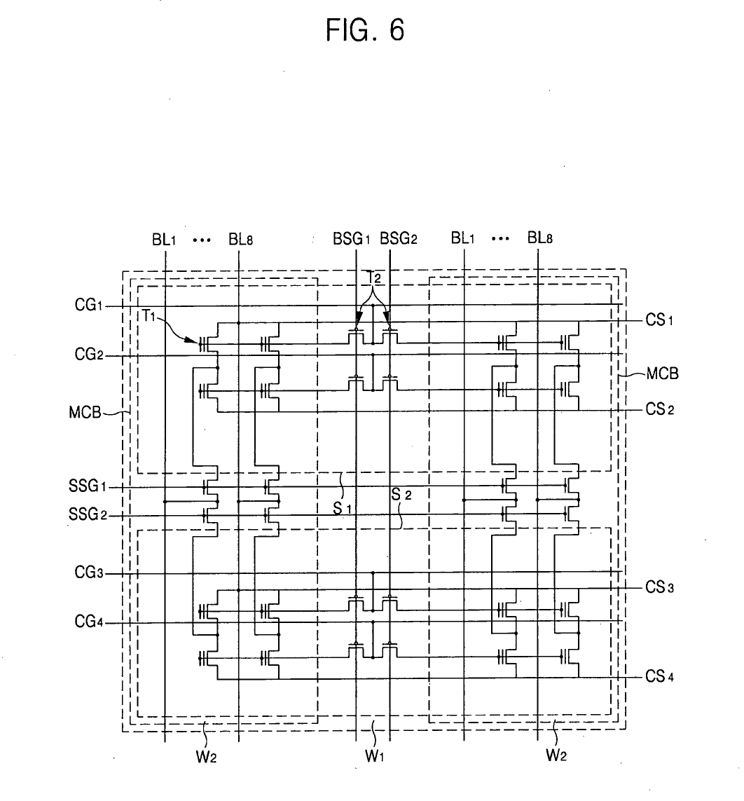

The non-volatile memory devices according to the above embodiments can be embodied by a 1-transistor (1T) NOR cell array instead of a conventional 2-transitor (2T) NOR cell array comprising two transistors of a selection transistor and a memory transistor, which will be described in detail with reference to FIG. 6. FIG. 6 is a circuit diagram illustrating the structure of a cell embodied by the non-volatile memory device of FIG. 1, in detail, the 1-T NOR cell array.

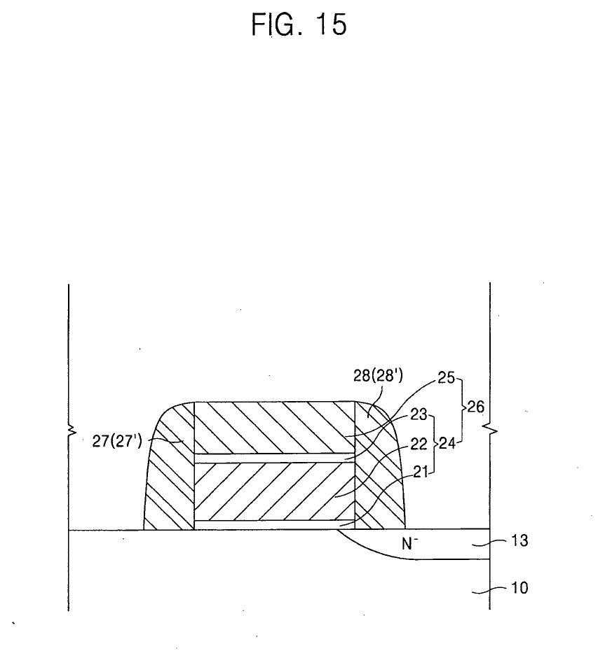

As shown in FIG. 6, the non-volatile memory devices according to the above embodiments comprise a memory transistor T₁ and a high voltage switching device T₂ selecting the memory transistor T₁. The memory transistor T₁ can comprise the gate structure 26 of FIG. 1 or 26′ of FIG. 4 that does not overlap the source region 12 of FIG. 1 or 4 and at least partially overlaps the drain region 15 of FIG. 1 or 4 on the semiconductor substrate 10 of FIG. 1 or 4 having the source/drain regions 12 of FIG. 1 or 15 of FIG. 4 respectively formed at both sides of the channel region 11 of FIG. 1 or 4, and the spacers 27 and 28 of FIG. 1 or 27′ and 28′ of FIG. 4 arranged at both sides of the gate structure 26 of FIG. 1 or 26′ of FIG. 4 and formed of a low-dielectric-constant material. A plurality of the memory transistors T₁ constitute a memory cell block (MCB).

The control gates of the memory transistors T₁ located in the MCB are connected by a control gate line Cᵢ, for example, CG₁, CG₂, CG₃, and CG₄, for each row. Also, the memory transistors T₁ are connected to a common source line CSᵢ, for example, CS₁, CS₂, CS₃, and CS₄. The common source line CSᵢ can be formed for each column, each row, each sector, or the whole memory.

The high voltage switching device T₂ is located near the MCB. The high voltage switching device T₂ programs or erases the memory cell in units of one byte, that is, eight bits, and takes the form of a switching transistor for each one byte memory cell to realize a byte selection operation of the memory cell. The high voltage switching device T₂ divides a global control gate line CGᵢ, for example, CG₁, CG₂, CG₃, and CG₄, into a local control gate line CGᵢₙ, for example, CG₁₁, CG₁₂, CG₂₁, CG₂₂, CG₃₁, CG₃₂, CG₄₁, and CG₄₂, extending over a single byte or word, and addressed by a byte selection gate line BSG₁, for example, BSG₁, . . . BSG₈, extending parallel to a bit line BLᵢ, for example, BL₁, . . . BL₈. Also, a sector Sₘ, for example, S₁ and S₂, is defined using a sector selection gate line SSGₘ, for example, SSG₁ and SSG₂, to reduce a bit line capacitance during the memory reading.

A byte column is arranged in a separate P-well W₂, for example, a pocket P-well, that is separated from N-well W₁, for example, a high voltage N-well (HVW). The high voltage switching device T₂ located in the N-well W₁ may be, for example, a PMOS transistor.

In the non-volatile memory devices according to the embodiments of the present invention embodied in the above-described 1T-NOR cell array, since a low-dielectric-constant material is applied to the spacer, when a relatively high voltage is applied to the control gate, the offset region of the source region is not turned on so that the selected cell can be programmed using the FN tunneling method. In addition, the non-volatile memory devices according to the embodiments of the present invention can realize the 1T-NOR cell array so that, compared to the conventional 2T-NOR cell array, the cell can be programmed or erased in units of bytes so that a relatively high cell integration can be realized.

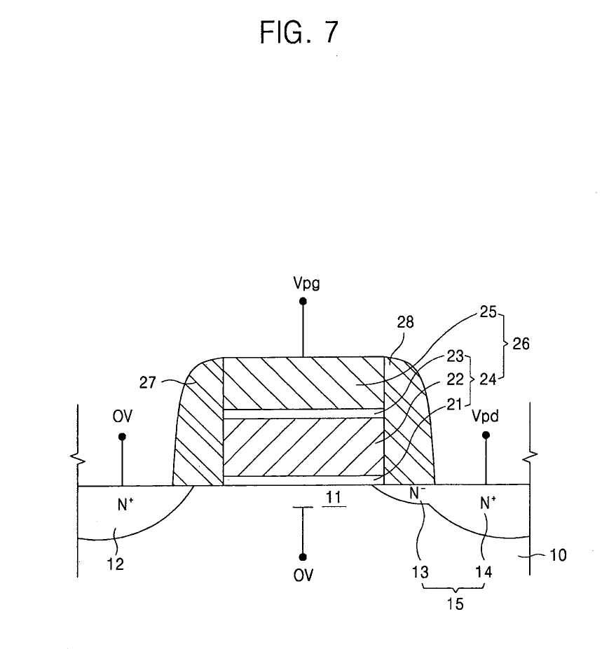

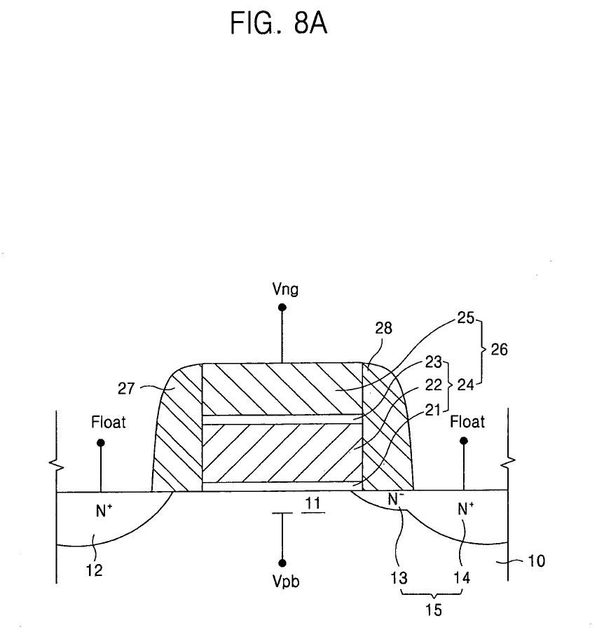

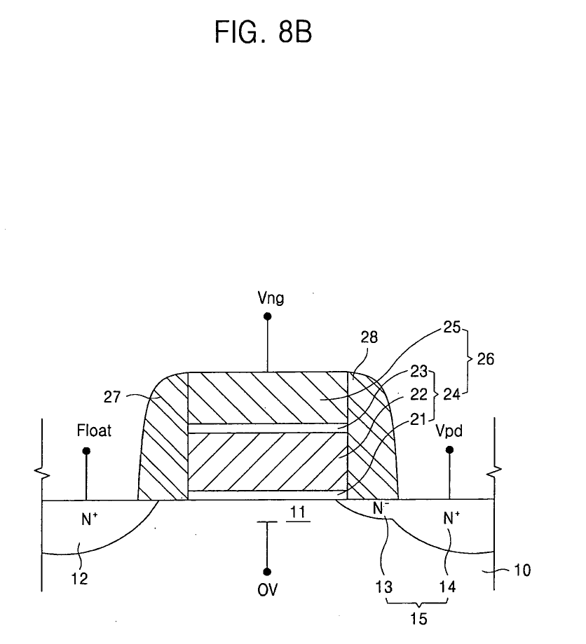

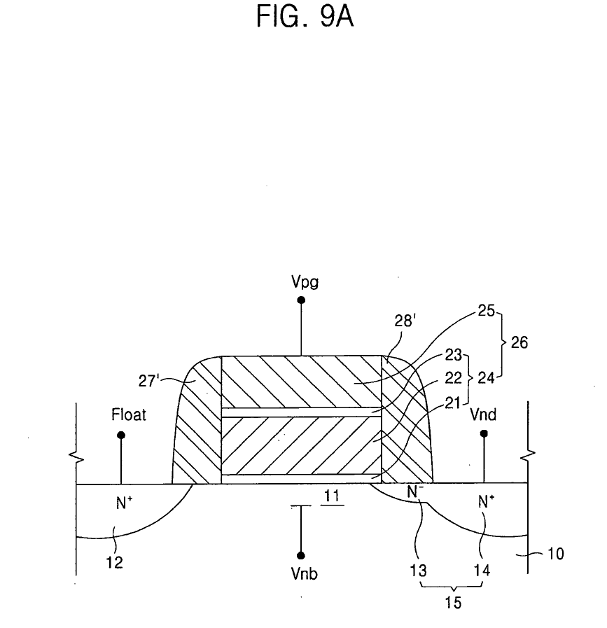

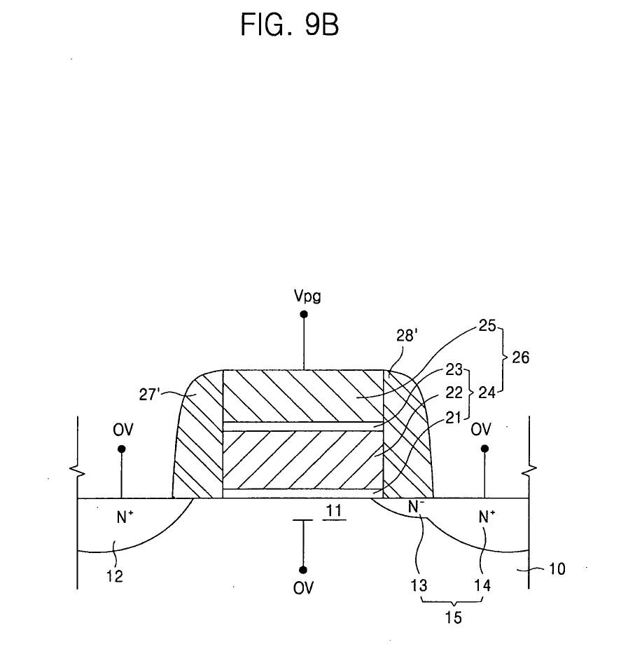

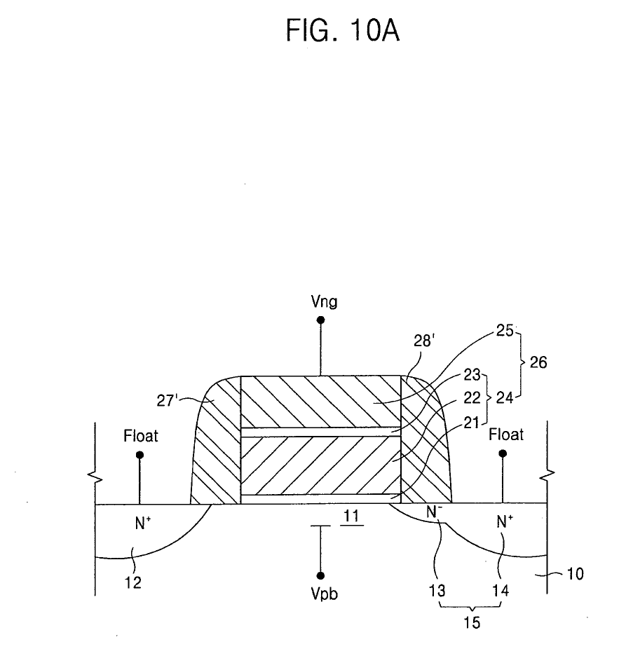

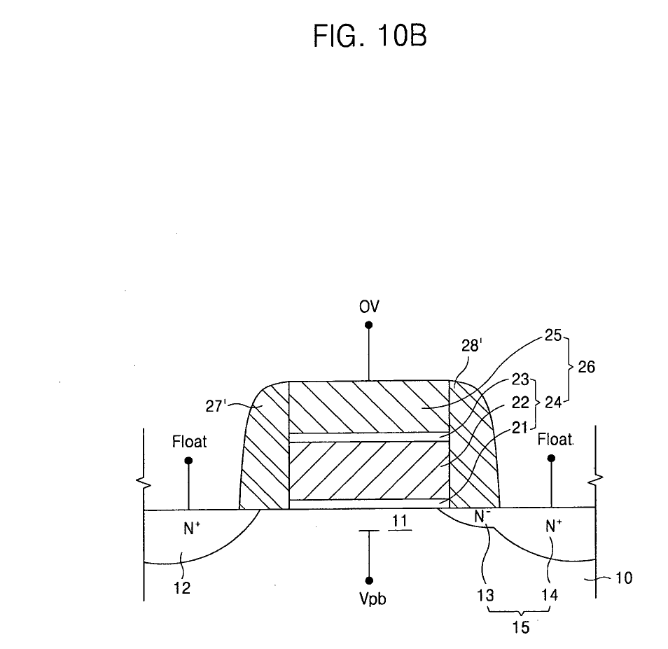

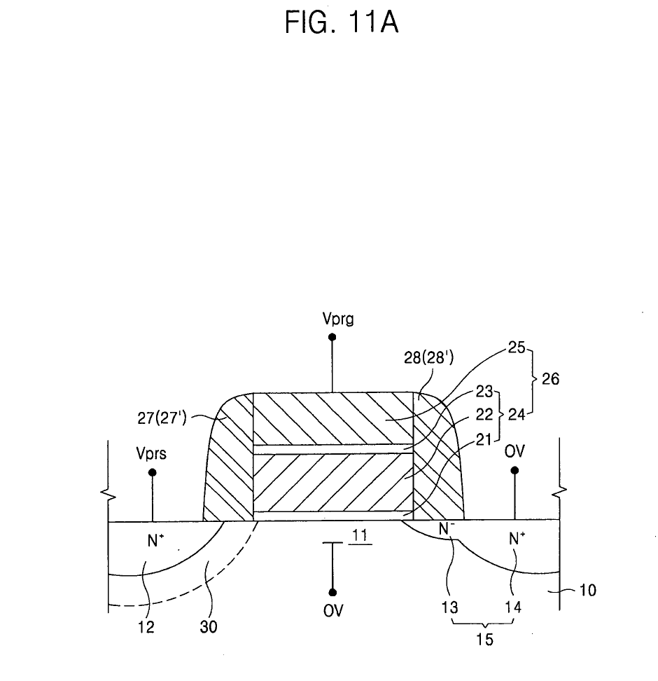

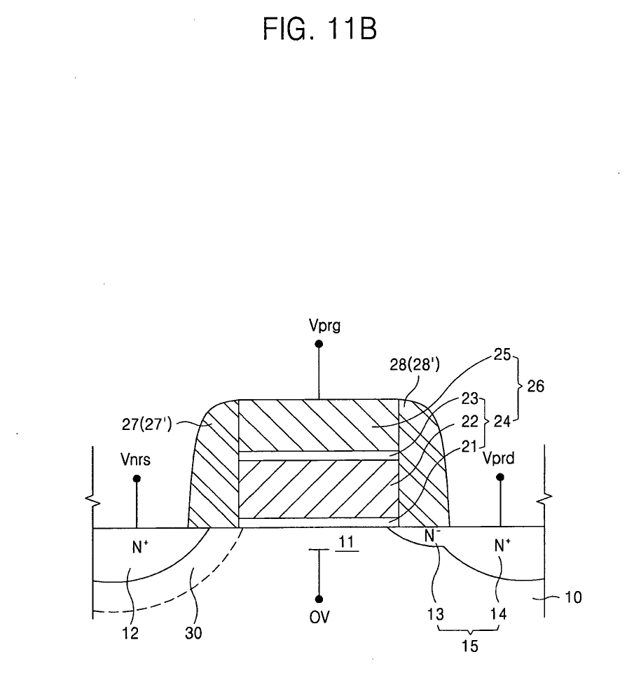

Next, the operation bias method of the non-volatile memory device according to an embodiment of the present invention will be described with reference to FIGS. 7 through 11B. FIG. 7 is a cross-sectional view illustrating a programming method of the non-volatile memory device of FIG. 1. FIGS. 8A and 8B are cross-sectional views illustrating an erasing method of the non-volatile memory device of FIG. 1. FIGS. 9A and 9B are cross-sectional views illustrating another programming method of the non-volatile memory device of FIG. 1. FIGS. 10A and 10B are cross-sectional views illustrating another erasing method of the non-volatile memory device of FIG. 1. FIGS. 11A and 11B are cross-sectional views illustrating a determination method of the non-volatile memory devices according to the above embodiments. Although in the present specification the charge accumulation region of the non-volatile memory device has a deposition structure of a tunnel insulation film, a floating gate, and a blocking insulation film, even when the charge accumulation region has a deposition structure of a tunnel insulation film, a nitride-based charge trap film, and a blocking insulation film, the below-described programming, erasing, and reading methods can be applied substantially the same.

In the programming and erasing methods when the spacer of the non-volatile memory device according to the embodiment of the present invention is formed of a high-dielectric-constant material, as shown in FIG. 7, by applying a positive voltage Vpg, for example, 12V, to the control gate 25, 0V to the source region 12, a positive voltage Vpd, for example, 6V, to the drain gate 15, and 0V to a bulk, electrons are injected from the source region 12 to the channel region 11 through the channel reversed to the fringe field and accelerated in the channel region 11. Thus, the selected cell is programmed in the channel hot electron (CHE) injection method in which the electrons are injected in the floating gate 22 of the charge accumulation region 24.

The erasure can be performed in a method of applying a negative voltage Vng, for example, −10V, to the control gate 25, floating the source/drain regions 12 and 15, and applying a positive voltage Vpb, for example, 8V, to the bulk, thus moving the electrons injected in the floating gate 22 toward the bulk in the FN tunneling method, as shown in FIG. 8A. Also, the erasure can be performed in a method of applying a negative voltage Vng to the control gate 25, floating the source region 12, and applying a positive voltage Vpb to the drain region 15, thus moving the electrons injected in the floating gate 22 toward the drain region 15 in the FN tunneling method as shown in FIG. 8B.

Next, the programming and erasing methods when the spacer of the non-volatile memory device according to the embodiment of the present invention is formed of a low-dielectric-constant material will be described. As shown in FIG. 9A, by applying a positive voltage Vpg, for example, 10V, to the control gate 25, floating the source region 12, applying a negative voltage Vnd, for example, −6V, to the drain gate 15, and applying a negative voltage Vnd to the bulk, or as shown in FIG. 9B, by applying a positive voltage Vpg, for example, 10V, to the control gate 25 and 0V to the source/drain regions 12 and 15 and the bulk, the electrons accelerated in the channel region 11 are injected to the floating gate 22 of the charge accumulation region 24 in the FN tunneling method so that the selected cell is programmed.

The erasure can be performed in a method of applying a negative voltage Vng, for example, −6V , to the control gate 25, floating each of the source/drain regions 12 and 15, and applying a positive voltage Vpb, for example, 10V, to the bulk, as shown in FIG. 10A, or by applying 0V to the control gate 25, floating each of the source/drain regions 12 and 15, and applying a positive voltage Vpb, for example, 10V, to the bulk, as shown in FIG. 10B, thus moving the electrons injected in the floating gate 22 toward the bulk in the FN tunneling method.

Next, a method for reading the non-volatile memory device according to an embodiment of the present invention will be described below. A selected cell can be read by applying a positive voltage Vprg, for example, 2.2V, to the control gate 25, a positive voltage Vprs, for example, 2.2V, to the source region 12, and 0V to the drain region 15 and the bulk, as shown in FIG. 11A, or by applying a positive voltage Vprg, for example, 4.0V, to the control gate 25, a positive voltage Vprs, for example, 2.0V, to the source region 15, a positive voltage Vprd, for example, 2.5V, to the drain region 15, and 0V to the bulk, as shown in FIG. 11B. This is to form a depletion region 30 in the offset region D of FIG. 1, so that the current flow in the channel region 11 and the source region 12 becomes insensitive to the gate voltage by drift which is the current flow type so that the selected cell can be read by the difference in voltage between the source region 12 and the bulk.

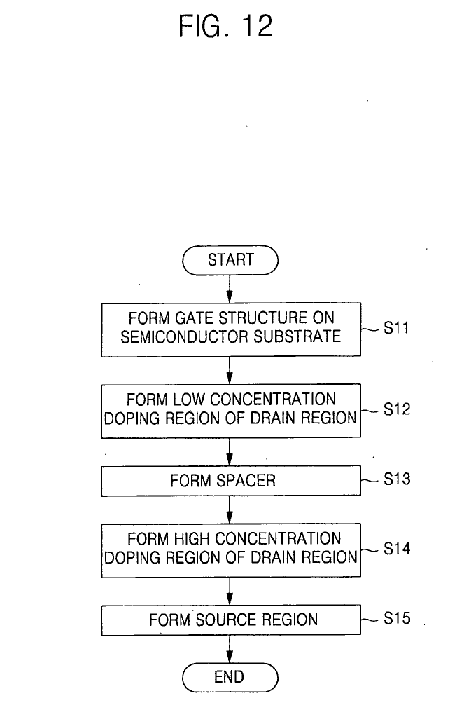

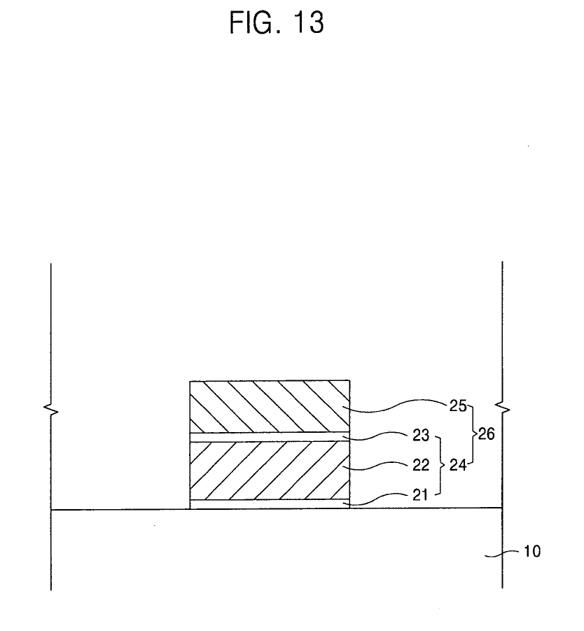

A method for fabricating a non-volatile memory device according to an embodiment of the present invention will be described with reference to FIGS. 1 and 12 through 17. FIG. 12 is a flow chart illustrating a method for fabricating a non-volatile memory device according to an embodiment of the present invention. FIGS. 13 through 17 are cross-sectional views sequentially illustrating the steps of the fabricating method of FIG. 12. Although in the present specification the charge accumulation region has a deposition structure of a tunnel insulation film, a floating gate, and a blocking insulation film, even when the charge accumulation region has a deposition structure of a tunnel insulation film, a nitride-based charge trap film, and a blocking insulation film, the below-described method for fabricating a non-volatile memory device according to an embodiment of the present invention can be applied.

As shown in FIG. 12, a gate structure is formed on a semiconductor substrate (SI 1). Although it is not shown in the drawings, a P-type semiconductor substrate, for example, is divided into an active region and a field region through a device separation process such as a shallow trench isolation (STI). The field region can be formed in a local oxidation of silicon (LOCOS) process or a self-aligned shallow trench isolation (SA-STI) process that simultaneously forms the floating gate and the active region.

Next, as shown in FIG. 13, the tunnel insulation film 21 is formed on the semiconductor substrate 10 to have a thickness of about 30 through 90 Å, preferably, about 60 Å. The tunnel insulation film 21 can be formed using thermal oxidation process or a chemical vapor deposition process. The tunnel insulation film 21 may be, for example, a silicon oxide film or silicon oxynitride film.

In general, since a capability for protecting data stored in a non-volatile memory device is mainly dependent on the reliability of the tunnel insulation film 21, the tunnel insulation film 21 works as a factor limiting the number of repetitions of the programming and erasing operations. A typical non-volatile memory device is required to be able to repeat the programming and erasing operations at least one million times. Thus, the tunnel insulation film 21 can be formed using a radical oxidation process under the conditions of a lower pressure of about 1 Torr or less, a temperature of about 800° C. or more, and a gas atmosphere of oxygen (O₂), hydrogen (H₂), and nitrogen (N₂). When the tunnel insulation film 21 is formed in the radical oxidation process, the thickness of the tunnel insulation film 21 can be appropriately controlled while density can be increased.

A conductive film (not shown) for a floating gate is formed on the tunnel insulation film 21 using a chemical vapor deposition process. The conductive film can be formed by forming a poly silicon film or amorphous silicon film having a thickness of about 300 through 700 Å, for example, about 500 Å, on the tunnel insulation film 21 and doping impurities in the poly silicon film or amorphous silicon film through POCl₃ diffusion, ion implantation, or in-situ doping. Since the floating gate 22 of the non-volatile memory device works as a tunneling source during the data programming and erasing operations, a conductive film for the floating gate 22 can be formed by an in-situ doped poly silicon film deposited using, for example, silane (SiH₄) and phosphine (Ph₃) gases that have a superior impurity doping uniformity and an easy electrode resistance control.

Next, the conductive film for the floating gate 22 in the field region is removed by a photolithographic process and insulated from the conductive film for the floating gate 22 of a neighboring memory cell. An ONO dielectric film combining a silicon oxide film exhibiting a superior leakage current characteristic and having a dielectric constant of about 3.9 and a silicon nitride film having a relatively high dielectric constant of about 7.0 is formed on the filed region where the conductive film is removed. The ONO dielectric film is for the blocking insulation film 23 and can be formed in a thermal oxide process or a chemical vapor deposition process.

A conductive film (not shown) for the control gate 25 formed of a poly silicon film or amorphous silicon film on the dielectric film for the blocking insulation film 23. The control gate 25 of the non-volatile memory device is a layer to which a voltage is applied to move the electrons in the semiconductor substrate 10 to the floating gate 22 or the electrons in the floating gate 22 to the semiconductor substrate during the data programming and erasing operations. Thus, when the conductive film for the control gate 25 is deposited, to prevent deterioration of an oxide film for the blocking insulation film 23 under the conductive film for the control gate 25, the conductive film for the control gate 25 is formed in a method of depositing a polycrystalline silicon film and performing impurity doping by POCl₃ or ion implantation or depositing an amorphous in-situ doped silicon film and performing phase-change to a crystalline silicon film through a heat treatment. The heat treatment is performed by a furnace heat treatment or rapid thermal annealing (RTA). The furnace heat treatment is performed for about 30 minutes at temperatures of about 600 through 950° C. while the RTA is performed at temperatures of about 800 through 1100° C.

Next, by sequentially dry etching the conductive film for the control gate 25, the dielectric film for the blocking insulation film 23, and the conductive film for the floating gate 22 by photolithography, the gate structure 26 comprising the charge accumulation region 25, which consists of the tunnel insulation film 21, the floating gate 22, and the blocking insulation film 23, and the control gate 25.

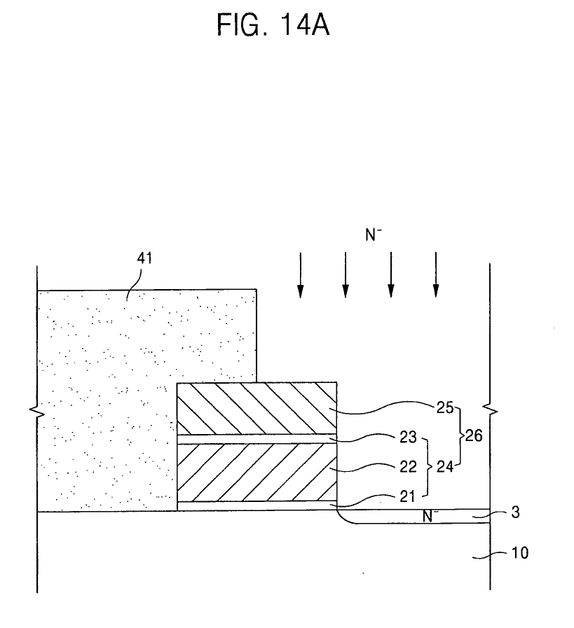

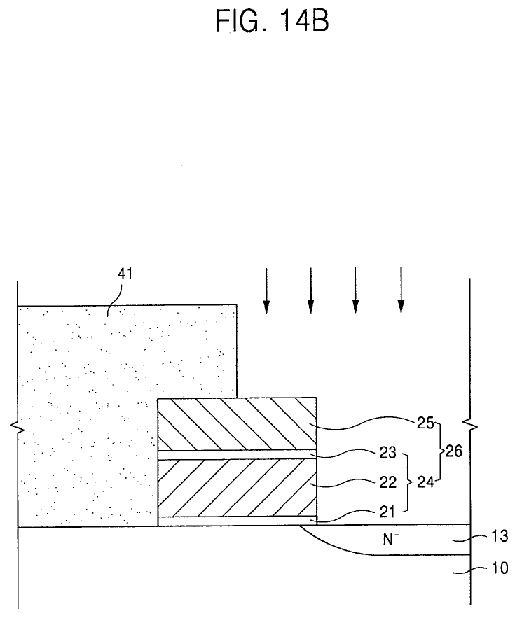

A low concentration doping region of the drain region is formed (S12). As shown in FIG. 14A, the gate structure 26 is coated with photoresist (not shown) and the photoresist is patterned to expose a portion of the semiconductor substrate 10 where the drain region 15 of FIG. 1 is formed. Then, low concentration N type impurity ions N⁻ are implanted by using the gate structure 26 and a photoresist pattern 41 as ion implantation masks so that a low concentration doping region 3 of the drain region 15 of FIG. 1 is formed. The low concentration doping region 3 is formed in the semiconductor substrate 10 aligned along the side wall of the gate structure 26. Although it is not shown in the drawings, halo ions can be implanted in the low concentration doping region 3 to restrict the punch-through phenomenon. That is, P type impurity ions can be implanted in the low concentration doping region 3 at a predetermined inclination angle using the gate structure 26 and the photoresist pattern 41 as an ion implantation mask. Also, as shown in FIG. 14B, heat treatment is performed to the semiconductor substrate 10. In FIG. 14B, a low concentration doping region 13 is diffused by the heat treatment.

Next, a spacer is formed (S13). As shown in FIG. 15, the photoresist pattern 41 of FIG. 14B is removed and a material having a high dielectric constant, for example, silicon nitride (Si₃N₄), aluminum oxide (Al₂O₃), or hafnium oxide (HfO₂), or a material having a low dielectric constant, for example, a film (not shown) formed of fluorinated silica glass or porous silicon oxide, are deposited on the gate structure 26 and the semiconductor substrate 10 to a thickness of about 500 Å. The high- or low-dielectric-constant film can be formed at a low pressure of about 0.4 Torr or less to improve a step coverage.

The spacers 27, 27′, 28, and 28′ arranged at both side walls of the gate structure 26 are formed by anisotropically etching the high- or low-dielectric-constant film.

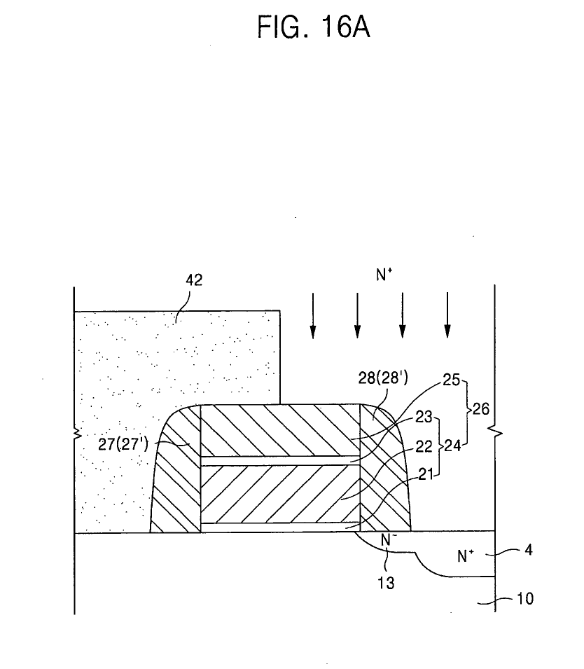

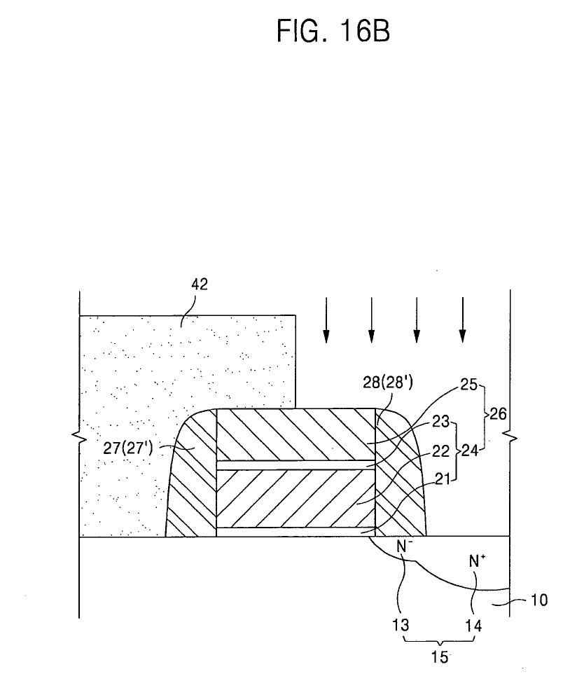

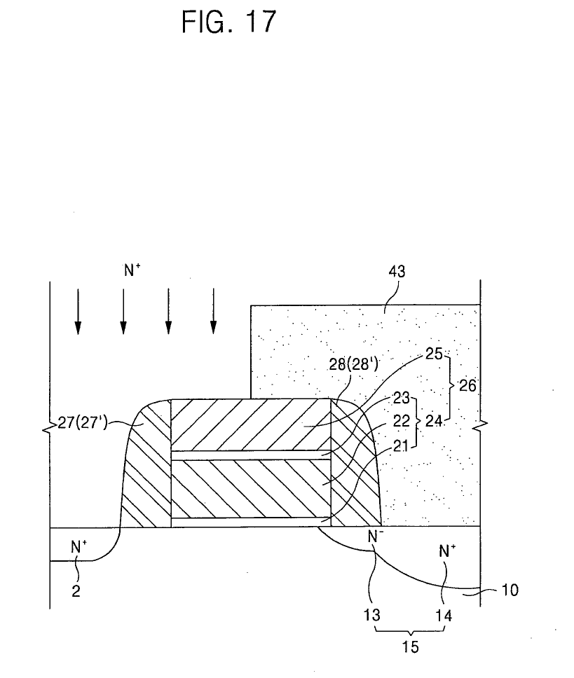

Next, a high concentration doping region of the drain region is formed (S14). As shown in FIG. 16A, photoresist (not shown) is coated on the gate structure 26 and the spacers 27, 27′, 28, and 28′ arranged at both side walls of the gate structure 26 and patterned to expose a portion of the semiconductor substrate 10 where the drain region 15 of FIG. 1 is formed. Then, high concentration N-type impurity ions N⁺ are implanted using the gate structure 26, the spacers 27, 27′, 28, and 28′, and a photoresist pattern 42, as ion implantation masks, to form the high concentration doping region 4 of the drain region 15 of FIG. 1. The high concentration doping region 4 is formed in the semiconductor substrate 10 aligned along an end portion of the spacer. Also, as shown in FIG. 16B, heat treatment is performed to the semiconductor substrate 10. In FIG. 16B, the high concentration doping region 14 is diffused by the heat treatment. Next, the source region is formed (S15). As shown in FIG. 17, the photoresist pattern 42 of FIG. 16B is removed and photoresist (not shown) is coated on the gate structure 26 and the spacers 27, 27′, 28, and 28′ arranged at both side walls of the gate structure 26 and patterned to expose a portion of the semiconductor substrate 10 where the source region 12 of FIG. 1 is formed. Then, high concentration N-type impurity ions N⁺ are implanted using the gate structure 26, the spacers 27 and 28, and a photoresist pattern 43, as ion implantation masks, to form the source region 2. Since the gate structure 26 and the source region 2 do not overlap each other, the offset region D of FIG. 1 is formed. The heat treatment is performed to the semiconductor substrate 10 formed the source region 2 so that the memory transistor of the non-volatile memory device is complete as shown in FIG. 1.

As described above, by separating the impurity ion implantation process to form the source region 12 and the drain region 15, the control of the offset region D of the source region 12 is simplified. Then, a non-volatile memory device is complete through a method for fabricating a non-volatile memory device.

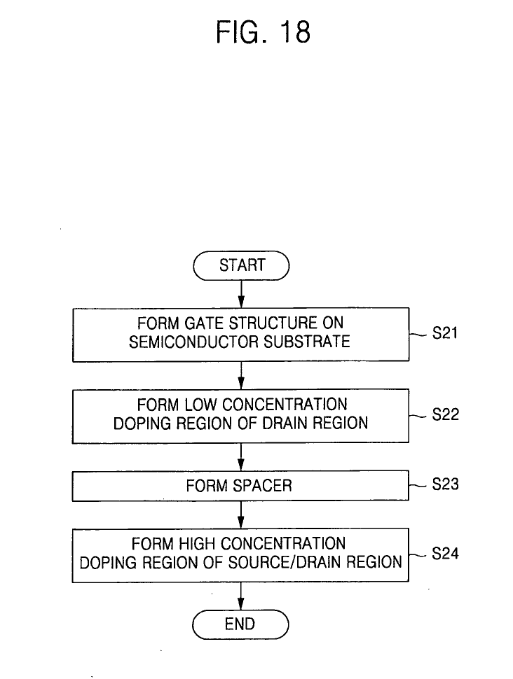

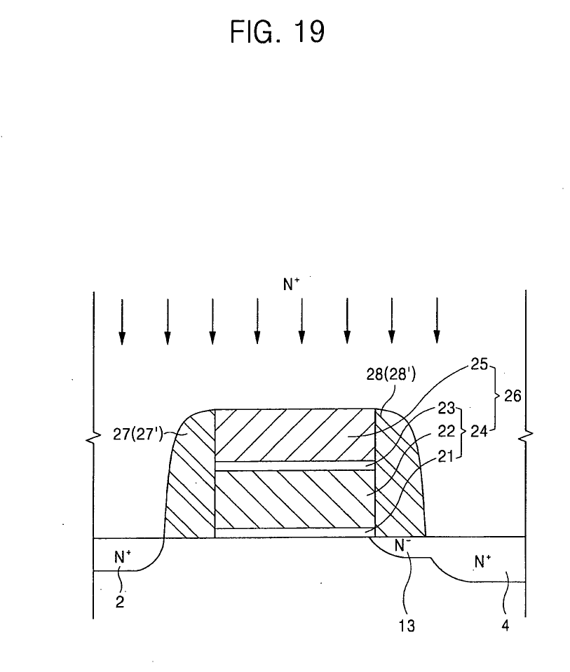

A method for fabricating a non-volatile memory device according to another embodiment of the present invention will be described with reference to FIGS. 1, 13 through 15, 18, and 19. FIG. 18 is a flow chart illustrating a method for fabricating a non-volatile memory device according to another embodiment of the present invention. FIG. 19 is a cross-sectional view illustrating an intermediate structure during the fabricating method of FIG. 18. Although in the present specification the charge accumulation region has a deposition structure of a tunnel insulation film, a floating gate, and a blocking insulation film, even when the charge accumulation region has a deposition structure of a tunnel insulation film, a nitride-based charge trap film, and a blocking insulation film, the below-described method for fabricating a non-volatile memory device according to another embodiment of the present invention can be applied.

As shown in FIG. 13, the gate structure 26 is formed on the semiconductor substrate 10 (S21 of FIG. 18). As shown in FIGS. 14A and 14B, the low concentration doping region 13 of the drain region 15 of FIG. 4 is formed by using the photoresist pattern 41 exposing the gate structure 26 and the drain region 15 of FIG. 4 as an ion implantation mask (S22 of FIG. 18). As shown in FIG. 15, the spacers 27, 27′, 28, and 28′ comprising a high- or low-dielectric-constant material and arranged at both side walls of the gate structure 26 are formed (S23 of FIG. 18).

Next, the high concentration doping region of the source region and the drain region is formed (S24 of FIG. 18). As shown in FIG. 19, the high concentration doping region 4 of the source region 12 of FIG. 1 and the drain region 15 of FIG. 1 is formed by implanting the high concentration N-type impurity ions N⁺ in the semiconductor substrate using the gate structure 26 and the spacers 27, 27′, 28, and 28′ arranged at both side walls of the gate structure 26 as ion implantation masks. The offset region D of FIG. 1 that does not overlap the gate structure 26 and the source region 12 of FIG. 1 is formed. By performing heat treatment to the offset region D of FIG. 1, the memory transistor of the non-volatile memory device as shown in FIG. 1 is complete.

As described above, by unifying an impurity ion implantation process to form the high concentration doping region 14 of the source region 12 and the drain region 15, the number of steps can be reduced. The non-volatile memory device is complete according to a typical method for fabricating a non-volatile memory device.

While this invention has been particularly shown and described with reference to preferred embodiments thereof, it will be understood by those skilled in the art that various changes in form and details may be made therein without departing from the spirit and scope of the invention as defined by the appended claims.

As described above, according to the above-described embodiments of the present invention, the non-volatile memory device comprising the source region not overlapping the gate structure and the drain region overlapping the gate structure prevents the voltage drop between the source/drain regions by the punch-through of the drain voltage by the offset region of the source region so that a program defect is prevented. Also, according to the embodiments of the present invention, by controlling the dielectric constant of the spacer film of the non-volatile memory device, the potential of the offset region turned on to the fringe field is controlled so as to selectively program a selected cell in the channel h0t electron (CHE) injection or FN tunneling method as necessary. Furthermore, the non-volatile memory device according to the embodiments of the present invention can maintain low power consumption during programming and can be applied to a variety of SOC (system-on-chip) applications.

What is claimed is:

1. A non-volatile memory device comprising:
a semiconductor substrate having source/drain regions formed at both ends of a channel region;
a gate structure forming an offset region by being separated a predetermined distance from the source region and comprising a charge accumulation region and a control gate sequentially deposited in the channel region to at least partially overlap the drain region; and
a spacer arranged at each of both side walls of the gate structure, wherein a threshold voltage value of the offset region changes depending on a dielectric constant of the spacer.

2. The non-volatile memory device of claim 1, wherein the spacer comprises a high-dielectric-constant material.

3. The non-volatile memory device of claim 2, wherein the high-dielectric-constant material is at least one material selected from the group consisting of silicon nitride (Si₃N₄), aluminum oxide (Al₂O₃), and hafnium oxide (HfO₂).

4. The non-volatile memory device of claim 2, wherein the memory device is programmable using a channel hot electron injection method.

5. The non-volatile memory device of claim 1, wherein the spacer comprises a low-dielectric-constant material.

6. The non-volatile memory device of claim 4, wherein the low-dielectric-constant material is at least one material selected from the group consisting of fluorinated silica glass and porous silicon oxide (SiO₂).

7. The non-volatile memory device of claim 4, wherein the memory device is programmable using an FN tunneling method.

8. The non-volatile memory device of claim 1, wherein the drain region comprises a low concentration doping region substantially aligned along the side wall of the gate structure and a high concentration doping region substantially aligned along an end position of the spacer.

9. The non-volatile memory device of claim 1, wherein the charge accumulation region comprises a deposition structure of a tunnel insulation film, a floating gate, and a blocking insulation film.

10. The non-volatile memory device of claim 1, wherein the charge accumulation region comprises a deposition structure of a tunnel insulation film, a nitride-based charge trap film, and a blocking insulation film.

11. A method for fabricating a non-volatile memory device, the method comprising:
forming a gate structure comprising a charge accumulation region and a control gate on a semiconductor substrate;
forming a spacer arranged at both side walls of the gate structure and including a high- or low-dielectric-constant material;
forming a drain region in the semiconductor substrate using the gate structure and the spacer as ion implantation masks; and
forming a source region in the semiconductor substrate using the gate structure and the spacer as ion implantation masks.

12. The method of claim 11, wherein the drain region and the source region are simultaneously or separately formed.

13. The method of claim 11, further comprising forming a low concentration doping region of the drain region using the gate structure as an ion implantation mask before the spacer is formed.

14. The method of claim 11, wherein the high-dielectric-constant material is at least one material selected from the group consisting of silicon nitride (Si₃N₄), aluminum oxide (Al₂O₃), and hafnium oxide (HfO₂).

15. The method of claim 11, wherein the low-dielectric-constant material is at least one material selected from the group consisting of fluorinated silica glass and porous silicon oxide (SiO₂).

16. The method of claim 11, wherein the charge accumulation region comprises a deposition structure of a tunnel insulation film, a floating gate, and a blocking insulation film.

17. The method of claim 11, wherein the charge accumulation region comprises a deposition structure of a tunnel insulation film, a nitride-based charge trap film, and a blocking insulation film.
